(19) United States
(12) Patent Application Publication
(10) Pub. No.: US 2009/0149017 A1
(43) Pub. Date: Jun. 11, 2009

(54) METHOD OF CLEANING SEMICONDUCTOR SUBSTRATE, AND METHOD OF MANUFACTURING SEMICONDUCTOR DEVICE AND SEMICONDUCTOR SUBSTRATE PROCESSING APPARATUS FOR USE IN THE SAME

(75) Inventor: Makoto MIYAMOTO, Chiyoda-ku (JP)

Correspondence Address: OBLON, SPIVAK, MCCLELLAND MAIER & NEUSTADT, P.C., 1940 DUKE STREET, ALEXANDRIA, VA, 22314, US

(73) Assignee: Renesas Technology Corp., Tokyo (JP)

(21) Appl. No.: 12/365,937

(22) Filed: Feb. 5, 2009

Related U.S. Application Data
(62) Division of application No. 11/210,737, filed on Aug. 25, 2005.

(30) Foreign Application Priority Data
Aug. 26, 2004 (JP) 2004-246331

(51) Int. Cl. H01L 21/20

(52) U.S. Cl. 438/618; 257/E21.09

(57) ABSTRACT

A semiconductor substrate processing apparatus is provided with a cleaning process chamber containing a semiconductor substrate for performing a cleaning process on the semiconductor substrate. Connected to the cleaning process chamber is a cleaning liquid feeding pipe for supplying a cleaning liquid to the semiconductor substrate. A gas dissolving unit is provided in the midpoint of the cleaning liquid feeding pipe for dissolving a prescribed gas in ultrapure water. An inert gas or a reducing gas is dissolved as a prescribed gas in ultrapure water. A control unit is provided having a function of supplying the cleaning liquid with the prescribed gas dissolved therein to the semiconductor substrate subjected to the cleaning process before performing a dry process. Therefore, the surface of the semiconductor substrate is free from stains. Moreover, a metal interconnection does not elude.

### CROSS-REFERENCE TO RELATED APPLICATIONS

This application is a division of and claims the benefit of priority under 35 U.S.C. §120 from U.S. Ser. No. 11/210,737 filed Aug. 25, 2005, the entire contents of which are incorporated herein by reference, which claims priority under 35 U.S.C. § 119 from Japanese application No. 2004246331 filed Aug. 26, 2004.

Method of Cleaning Semiconductor Substrate, and Method of Manufacturing Semiconductor Device and Semiconductor Substrate Processing Apparatus for Use in the Same

### BACKGROUND OF THE INVENTION

1. Field of the Invention

The present invention relates to a method of cleaning a semiconductor substrate as well as a method of manufacturing a semiconductor device and a semiconductor substrate processing apparatus for use in the same. More specifically, the present invention relates to a method of cleaning a semiconductor substrate after a chemical mechanical polishing process and a method of manufacturing a semiconductor device using the same, and a semiconductor substrate processing apparatus for use in the method of cleaning a semiconductor substrate.

2. Description of the Background Art

A series of processes for manufacturing semiconductor devices includes a process of cleaning semiconductor substrates before forwarding the semiconductor substrates subjected to a prescribed process to the next process. In such a process, a single-wafer cleaning apparatus is conventionally used to clean and dry semiconductor substrates. In a single-wafer cleaning apparatus, semiconductor substrates set in a carrier for transferring the semiconductor substrates are transferred one by one to a process chamber of the cleaning apparatus. The semiconductor substrate transferred to the process chamber is rotated with the semiconductor substrate horizontally held by a spinner. While the semiconductor substrate is rotated, a prescribed cleaning liquid is supplied to the semiconductor substrate from at least one of above and below to clean the semiconductor substrate.

When the cleaning with the cleaning liquid is completed, ultrapure-water rinsing liquid or the like is then supplied to the semiconductor substrate for cleaning (rinsing) the semiconductor substrate. When the cleaning ultrapure water or the like is completed, the semiconductor substrate is rotated at the even higher rotation speed so that the semiconductor substrate is dried by shaking off the moisture and the like adhered to the surface of the semiconductor substrate. Meanwhile, dry air or nitrogen may be supplied to the semiconductor substrate to dry the semiconductor substrate.

When the drying of the semiconductor substrate is completed, the semiconductor substrate is removed from the process chamber and returned to the carrier. In the cleaning apparatus, a plurality of process chambers may be provided in some cases. Furthermore, different process chambers may be used appropriately depending on the processes such as the kinds of cleaning liquids and drying. Alternatively, the processes using multiple cleaning liquids may successively be performed in one process chamber.

The document disclosing such a cleaning method include, for example, Patent Document 1 (Japanese Patent Laying-Open No. 09-293702) or Patent Document 2 (Japanese Patent Laying-Open No. 10-032183). In the cleaning method described in Patent Document 1, a spinner holding a semiconductor substrate horizontally is rotated to shake off the moisture adhered to the surface of the semiconductor substrate using a centrifugal force, whereby the semiconductor substrate is dried. Specifically, Cited Document 1 is characterized in that, in a centrifugal drying apparatus for drying a semiconductor substrate, the drying of the semiconductor substrate is promoted by providing a drying guide covering the semiconductor substrate for guiding a drying fluid to the surface of the semiconductor substrate and blowing nitrogen gas or the like to the semiconductor substrate through the drying guide or by supplying isopropyl alcohol as a volatile organic solvent.

The cleaning apparatus and the cleaning method described in Patent Document 2 are characterized in that, after the process of cleaning a semiconductor substrate, the semiconductor substrate is dried by switching the rotation of the semiconductor substrate to the high speed mode and also by blowing a prescribed gas including nitrogen or like to the semiconductor substrate from a movable nozzle installed above the semiconductor substrate.

In recent years, Chemical Mechanical Polishing process (abbreviated hereinafter as “CMP process”) is performed on a semiconductor substrate to form a prescribed metal interconnection in the process of manufacturing a semiconductor device, and the cleaning (single-wafer cleaning) performed on the semiconductor substrate subjected to the CMP process has been increasingly important.

The metal interconnection is formed by first forming a groove portion in an interlayer insulating film, performing a CMP process on a metal film formed on the interlayer insulating film to fill in the groove, and leaving the portion of the metal film located in the groove portion while removing the remaining portion. Many polishing grains or polishing liquid components are adhered on the surface of the semiconductor substrate subjected to the CMP process. The contamination level is therefore very high. Accordingly, normally, scrub cleaning is first performed in which the surface of the semiconductor substrate is cleaned using a roll brush of a polymeric material such as polyvinyl alcohol. The semiconductor substrate is thereafter transferred to a process chamber for spin cleaning in order to perform a spin cleaning process and a drying process on the semiconductor substrate.

A copper (Cu) interconnection is employed as the metal interconnection to improve the function of a semiconductor device, and an insulating film having a dielectric constant of about 2.0 to 3.7 is employed as the interlayer insulating film. Specifically, this insulating film is referred to as Low-k film as the value of the dielectric constant is relatively low as the interlayer insulating film. Recently, the techniques for processing a semiconductor substrate employing the Cu interconnection and the Low-k film have been actively developed.

The cleaning method employed for the semiconductor substrate employing the Cu interconnection and the Low-k film, however, has the following problems. Since the Low-k film is extremely hydrophobic, the semiconductor substrate cannot be dried perfectly using a cleaning apparatus, resulting in microscopic liquid drops. When the drops dry, stains are inevitably made where they dry. The stains are specifically referred to as watermarks. Moreover, the left drops cause the Cu interconnection to elute.

### SUMMARY OF THE INVENTION

The present invention is made to solve the aforementioned problems. It is one object of the present invention to provide a method of cleaning a semiconductor substrate while preventing stains on a surface of a semiconductor substrate and also preventing elution of metal interconnections. It is another object of the present invention to provide a method of manufacturing a semiconductor device using the same. It is yet another object of the present invention to provide a semiconductor substrate processing apparatus for use in such cleaning.

In a method of cleaning a semiconductor substrate in accordance with the present invention, a cleaning process and a drying process are performed on a semiconductor substrate. The method includes a step of supplying to the semiconductor substrate a cleaning liquid with a prescribed gas dissolved therein for preventing diffusion of oxygen in atmosphere into a liquid drop left on a surface of the semiconductor substrate, after performing the cleaning process and before performing the drying step.

In accordance with the present invention, a semiconductor substrate processing apparatus including a function of performing a cleaning process and a drying process on a semiconductor substrate includes a gas dissolving unit and a control unit. The gas dissolving unit dissolves in a cleaning liquid a prescribed gas for preventing diffusion of oxygen in atmosphere into a liquid drop left on a surface of a semiconductor substrate after the cleaning process is performed. The control unit has a function of supplying the cleaning liquid in which a prescribed gas is dissolved by the gas dissolving unit to the semiconductor substrate after the cleaning process and before the drying process.

In a method of manufacturing a semiconductor device in accordance with the present invention, a cleaning process and a drying process are performed on a semiconductor substrate. The method includes a step of supplying a cleaning liquid with a prescribed gas dissolved therein to the semiconductor substrate after performing the cleaning process and before performing the drying process.

Another method of manufacturing a semiconductor device in accordance with the present invention includes the following steps. An interlayer insulating film is formed at a main surface of a semiconductor substrate. A prescribed groove corresponding to an interconnection pattern is formed in the interlayer insulating film. A metal film is formed on the interlayer insulating film to fill in the groove. An interconnection is formed in the groove by performing a chemical mechanical polishing process on the metal film for selectively leaving the metal film in the groove. The surface of the semiconductor substrate is cleaned after the polishing process (a first cleaning step). The surface of the semiconductor substrate is cleaned after the first cleaning step (a second cleaning step). The surface of the semiconductor substrate is dried after the second cleaning step. A cleaning liquid in which a prescribe gas is dissolved is used in the second cleaning step.

In a method of cleaning a semiconductor substrate in accordance with the present invention, a cleaning liquid with a prescribed gas dissolved therein is supplied to a semiconductor substrate after a cleaning process and before a drying process, thereby preventing diffusion of oxygen in the atmosphere into liquid drops left on the semiconductor substrate during the drying process or after the drying. Therefore, the formation of stains on the surface of the semiconductor substrate and the elution of the metal interconnection can be prevented.

In a semiconductor substrate processing apparatus in accordance with the present invention, a cleaning liquid in which a prescribed gas is dissolved by a gas dissolving unit is supplied by a control unit to the semiconductor substrate after a cleaning process is performed and before a drying process is performed, thereby preventing diffusion of oxygen in the atmosphere into liquid drops left on the semiconductor substrate during the drying process or after the drying. Therefore, the formation of stains on the surface of the semiconductor substrate and the elution of the metal interconnection can be prevented.

In a method of manufacturing a semiconductor device in accordance with the present invention, a cleaning liquid with a prescribed gas dissolved is supplied to a semiconductor substrate after a cleaning process and before a drying process, thereby preventing diffusion of oxygen in the atmosphere into liquid drops left on the semiconductor substrate during the drying process or after the drying. Therefore, the formation of stains on the surface of the semiconductor substrate and the elution of the metal interconnection can be prevented.

In another method of manufacturing a semiconductor device in accordance with the present invention, a cleaning liquid with a prescribed gas dissolved is used to clean a surface of a semiconductor substrate in the second cleaning step before the surface of the semiconductor substrate is dried after the first cleaning step, thereby preventing diffusion of oxygen in the atmosphere into liquid drops left on the semiconductor substrate during the drying or after the drying of the semiconductor substrate. Therefore, the formation of stains on the surface of the semiconductor substrate and the elution of interconnections can be prevented.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 shows a mechanism of watermark formation in accordance with an embodiment of the present invention.

FIG. 2 shows a foreign substance (particle) map where a cleaning liquid including no dissolved gas is supplied to a semiconductor substrate in accordance with the embodiment.

FIG. 3 shows a foreign substance (particle) map where a cleaning liquid with nitrogen gas dissolved is supplied to a semiconductor substrate.

FIG. 4 shows a foreign substance (particle) map where a cleaning liquid with oxygen gas dissolved is supplied to a semiconductor substrate.

FIG. 5 shows a result of a comparative evaluation between a cleaning method using a cleaning liquid with nitrogen gas dissolved and a conventional cleaning method in accordance with a second embodiment of the present invention.

FIG. 6 shows the number of resultant watermarks where cleaning liquids with a variety of gases respectively dissolved in ultrapure water are used in accordance with a third embodiment of the present invention.

FIG. 7 is a cross sectional view showing a Cu interconnection pattern for use to evaluate the prevention of Cu elution in Cu interconnection in accordance with a fourth embodiment of the present invention.

FIG. 8 shows a resultant depth of a concave portion of a Cu interconnection where cleaning liquids with a variety of gases respectively dissolved in ultrapure water are used in accordance with the fourth embodiment.

FIG. 9 is a graph showing the dependence of the number of watermarks on nitrogen gas solubility in accordance with a fifth embodiment of the present invention.

FIG. 10 is a conceptual diagram showing a configuration of a semiconductor substrate processing apparatus in accordance with a sixth embodiment of the present invention.

FIG. 11 is a conceptual diagram showing a configuration of a semiconductor substrate processing apparatus in accordance with a seventh embodiment of the present invention.

FIG. 12 is a conceptual diagram showing a configuration of a semiconductor substrate processing apparatus in accordance with a modification to the seventh embodiment.

FIG. 13 is a flowchart showing process steps using a product wafer in accordance with an eighth embodiment of the present invention.

FIG. 14 is a schematic view showing the cleaning in the cleaning process at step S2 shown in FIG. 13.

FIG. 15 is a schematic view showing the cleaning in the cleaning process at step S3 shown in FIG. 13.

### DESCRIPTION OF THE PREFERRED EMBODIMENTS

### First Embodiment

As described above, conventionally, stains (watermarks) are formed where liquid drops left on a semiconductor substrate dry after the cleaning of the semiconductor substrate. Here, the findings (mechanism) about those watermarks and a cleaning method for preventing the watermarks based on the model will be described.

The Low-k film (low dielectric constant film) for use as an interlayer insulating film for higher performance of a semiconductor device effectively improves the property of the semiconductor device with a lower dielectric constant as compared with the conventional silicon oxide film (SiO₂). However, this Low-k film exhibits extremely high hydrophobicity, which makes it difficult to clean a semiconductor substrate after a CMP process is performed on the semiconductor substrate. More specifically, watermarks are formed on the surface of the semiconductor substrate after being dried. An SiOC film is typically used as Low-k film. Since the mechanism of watermark formation is still unknown even with the typical SiOC film, no effective measures can be taken for reducing the watermarks.

The inventors have clarified this mechanism of watermark formation through various studies to conceive the present invention as a solution to this problem. The mechanism of watermark formation in an SiOC film as a typical Low-k film will be described now. An SiOC film has a methyl (CH₃) group in a portion of the SiO2 film. The steric hindrance effect of the methyl group enables the value of the dielectric constant of the entire SiOC film to be decreased. In addition, the surface of the SiOC film exhibits strong hydrophobicity because of the existence of the methyl group.

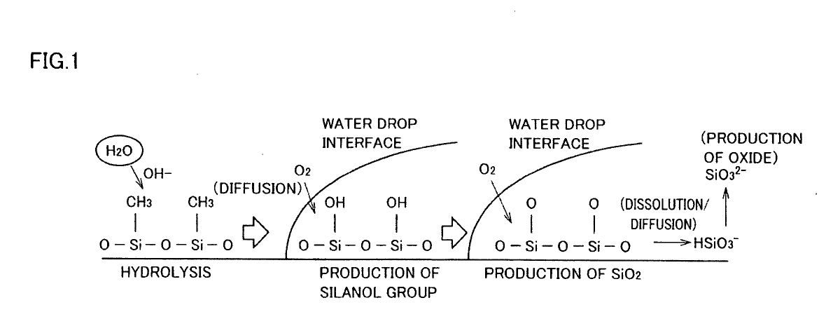

FIG. 1 shows a model of watermark production in an SiOC film which is clarified in accordance with the present invention. In summary, this mechanism of watermark production is based on a reaction model in which an SiOH group is formed by hydrolysis of SiOC and the SiOH group changes to SiO₂. This reaction model will be described in detail.

(1) First, a hydrolysis reaction takes place due to the presence of the alkyl group and the moisture in the SiOC as shown in the left portion of FIG. 1. A silanol group (Si—OH group) is formed as shown in the middle portion of FIG. 1. This hydrolysis reaction is promoted by the existence of an oxidizer or a reducer.

(2) Then, as shown in the right portion of FIG. 1, dehydration condensation between those adjacent silanol groups of the formed silanol groups which are present in the residual water drop after drying takes place, resulting in an SiO₂ bond. Alternatively, oxygen in the atmosphere dissolves and diffuses in the residual water drop to oxidize the silanol group, resulting in SiO₂.

(3) Then, the formed SiO₂ hydrates, resulting in silicic acid (H₂SiO₃).

(4) The resultant silicic acid dissolves and diffuses during the hydration.

(5) In addition, silicic acid dissociates, resulting in HSiO³⁻.

(6) The resultant HSiO³⁻ dissociates so that SiO₃²⁻ is formed and diffused, thereby promoting production of oxide.

As described above, the oxygen in the atmosphere diffuses into the drop left after drying, causing SiOC to change to SiO₂. Then, SiO₂ is deposited after the drop dries, and the deposited SiO₂ becomes a watermark.

An experiment for preventing watermark formation which is performed based on the aforementioned watermark formation mechanism and the result thereof will be described. As described above, the formation of watermarks is presumably caused by the diffusion of oxygen in the atmosphere into the drop left on the surface of the semiconductor substrate. Accordingly, in the experiment, in order to reduce the effect of the dissolved oxygen, a gas dissolving unit was provided for preliminarily dissolving a prescribed gas in water (ultrapure water) supplied to the semiconductor substrate processing apparatus so that liquid in which a prescribed gas is dissolved in ultrapure water was supplied as a cleaning liquid (rinsing liquid) to the semiconductor substrate before the drying step. It is noted that ultrapure water is high purity water as close as possible to H₂0, which is obtained by incorporating all the element techniques for purification (Rikagaku Jiten, the fifth edition, Iwanami Shoten).

First, a clean, 8-inch SiOC substrate was used as a semiconductor substrate. Nitrogen gas and oxygen gas were employed as the prescribed gas. A cleaning liquid having the nitrogen gas dissolved to a saturation level and a cleaning liquid having the oxygen gas dissolved to a saturation level were employed as the cleaning liquid. In addition, a cleaning liquid containing no dissolved gas was employed for comparison. An SiOC substrate having SiOC formed on a silicon substrate 8 inches in diameter, for example, by a spin coat method or chemical vapor deposition method was employed as the semiconductor substrate. It is noted that a dissolved oxygen concentration meter (manufactured by Horiba Seisakusho: OM-51) and a dissolved nitrogen concentration meter (manufactured by Orbisphere Inc.: 3610N2) were used for the measurement of the concentration of each gas dissolved in the cleaning liquid.

The time during which each cleaning liquid was supplied to the semiconductor substrate was set as 60 seconds. The conditions of drying process after supplying the cleaning liquid were set with the rotation speed of the semiconductor substrate at 3000 rpm and with the time for 20 seconds. The formation of watermarks on the surface of the semiconductor substrate after being dried were observed by a foreign substance inspection apparatus (manufactured by Hitachi Electronics Engineering: LS5000). It is noted that, before the evaluation of an SiOC substrate, it was confirmed that no particle (foreign substance) adhered to the ultrapure water itself and the semiconductor substrate during drying by performing an evaluation using the foreign substance inspection apparatus after De-Ionized Water (DIW) was supplied (rinsed) to the SiO₂ substrate for 600 seconds and then dried. It is noted that De-Ionized Water means ultrapure water containing no gas.

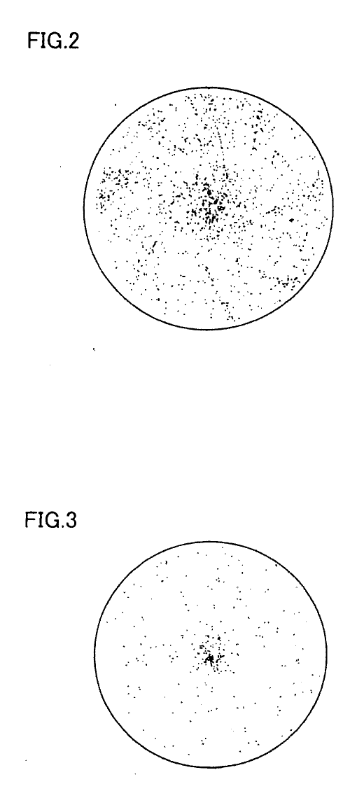

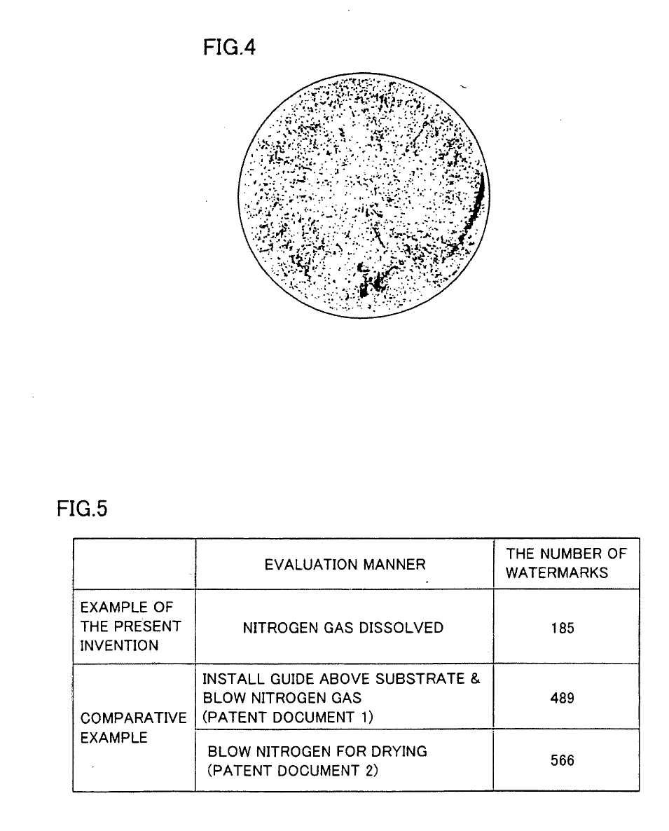

FIGS. 2-4 respectively show the evaluation results using the foreign substance inspection apparatus. FIG. 2 shows a foreign substance map where a cleaning liquid containing no dissolved gas is supplied to a semiconductor substrate and dried. FIG. 3 shows a foreign substance map where a cleaning liquid with nitrogen gas dissolved to a saturation level is supplied to a semiconductor substrate and dried. FIG. 4 shows a foreign substance map where a cleaning liquid with oxygen gas dissolved to a saturation level is supplied to a semiconductor substrate and dried. Each foreign substance map shows a foreign substance having a dimension of 0.27 μm or more.

As shown in FIGS. 2 and 4, in the cases of the cleaning liquid containing no dissolved gas and the cleaning liquid with oxygen gas dissolved, it was found that a number of watermarks were formed on the surface of the semiconductor substrate. On the other hand, as shown in FIG. 3, in the case of the cleaning liquid with nitrogen gas dissolved, although a certain amount of watermarks were found in the center portion of the semiconductor substrate, the watermarks were clearly less than when the cleaning liquid containing no dissolved gas and the cleaning liquid with oxygen gas dissolved were used.

The experiment result has proven that diffusion of oxygen into the drop left on the surface of the semiconductor substrate is prevented by supplying to the semiconductor substrate the cleaning liquid with nitrogen gas as an inert gas dissolved, thereby reducing the production of watermarks. On the other hand, it has also been proven in the case of the cleaning liquid with oxygen dissolved that the supply of a cleaning liquid with oxidizing gas dissolved to the semiconductor substrate is not effective in preventing the formation of watermarks, considering that the formation of watermarks was promoted in the case of the cleaning liquid with oxygen dissolved.

### Second Embodiment

Here, a comparative evaluation to a conventional cleaning method will be described, which was performed in order to confirm the effectiveness of the cleaning method using the cleaning liquid with nitrogen gas dissolved in accordance with the present invention. In the example of the present invention, a cleaning liquid with nitrogen gas dissolved was supplied to a semiconductor substrate before drying. On the other hand, the cleaning methods of blowing nitrogen gas as disclosed in Patent Document 1 and Patent Document 2 described above were employed as comparative examples. An SiOC substrate was used as a semiconductor substrate. The time during which a cleaning liquid with nitrogen gas dissolved was supplied to the semiconductor substrate was set as 60 seconds. The drying conditions were set with the rotation speed of the semiconductor substrate at 3000 rpm and the time for 20 seconds. The formation of watermarks on the surface of each semiconductor substrate after drying was observed by a foreign substance inspection apparatus. It is noted that two semiconductor substrates were evaluated for each condition in the foreign substance inspection.

The result is shown in FIG. 5. Each value shows the average number of foreign substances evaluated for two semiconductor substrates for each condition. As shown in FIG. 5, the cleaning method of the example in accordance with the present invention results in 185 foreign substances, while the cleaning method according to Patent Document 1 (comparative example) results in 489 and the cleaning method according to Patent Document 2 (comparative example) results in 566.

As described above, the number of watermarks in the cleaning method in accordance with the present invention is about one-third the number of watermarks in the conventional cleaning method, which has proven that the cleaning method in accordance with the present invention using the cleaning liquid with nitrogen gas dissolved is highly effective in preventing the formation of watermarks as compared with the conventional cleaning method.

### Third Embodiment

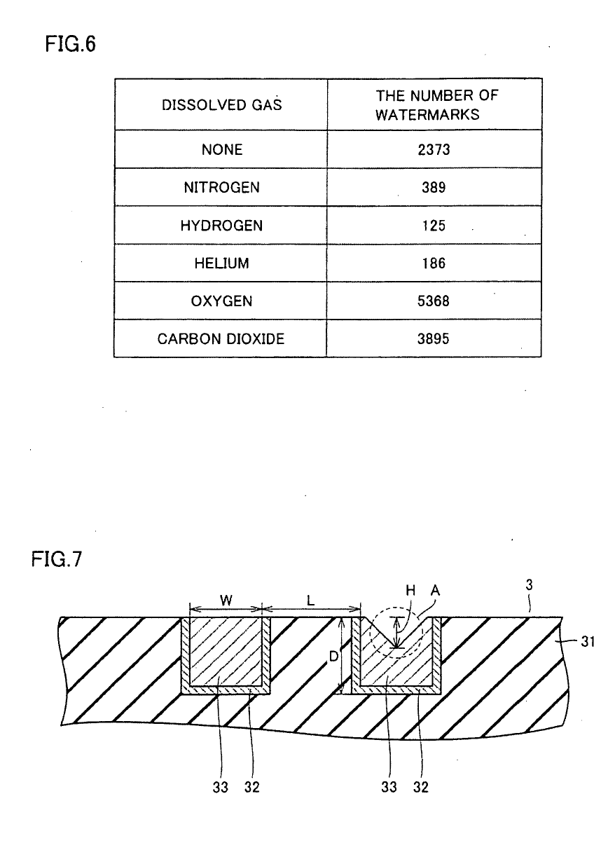

Here, the effect of preventing watermark formation using cleaning liquids respectively having a variety of gases dissolved in ultrapure water will be described. The evaluation conditions other than the kinds of gases were the same as the conditions described in the first embodiment. The result is shown in FIG. 6. As shown in FIG. 6, it was found that the number of watermarks was significantly less when cleaning liquids with nitrogen gas or helium dissolved as inert gas or a cleaning liquid with hydrogen gas dissolved as reducing gas was supplied to the semiconductor substrate than when a cleaning liquid having no gas dissolved or a cleaning liquid having oxygen or carbon dioxide dissolved as oxidizing gas was supplied to the semiconductor substrate.

It is noted that, although not shown in FIG. 6, it was also confirmed that the number of watermarks was significantly reduced when a cleaning liquid in which, for example, acetylene, ethylene, carbon monoxide, neon, methane, or the like was dissolved as alternative inert gas or reducing gas was supplied to the semiconductor substrate. Additionally, the similar effect was achieved also when a cleaning liquid in which the gas produced by mixing the inert gas and the reducing gas was dissolved into ultrapure water was supplied to the semiconductor substrate.

This evaluation has confirmed that the formation of watermarks can be prevented considerably by supplying to the semiconductor substrate a cleaning liquid in which an inert gas or a reducing gas or a mixture gas thereof is dissolved.

### Fourth Embodiment

Here, the evaluations about elution of Cu in a Cu interconnection will be described in which cleaning liquids having a variety of gases respectively dissolved therein are supplied to a semiconductor substrate having a Cu interconnection and a Low-k film formed therein in a manner similar to the third embodiment.

As shown in FIG. 7, such a semiconductor substrate was used as a semiconductor substrate in that a Cu interconnection 33 pattern was formed in a Low-k film (SiOC film) 31 with an interconnection width W of about 90 nm, a depth D of about 300 nm, and a distance L between interconnections of about 200 nm. A barrier metal 32 is formed between Cu interconnection 33 and Low-k film 31. After the cleaning liquids having a variety of gases respectively dissolved therein were supplied to the semiconductor substrate and dried, the elution state of the Cu interconnection was evaluated by an atomic force microscope.

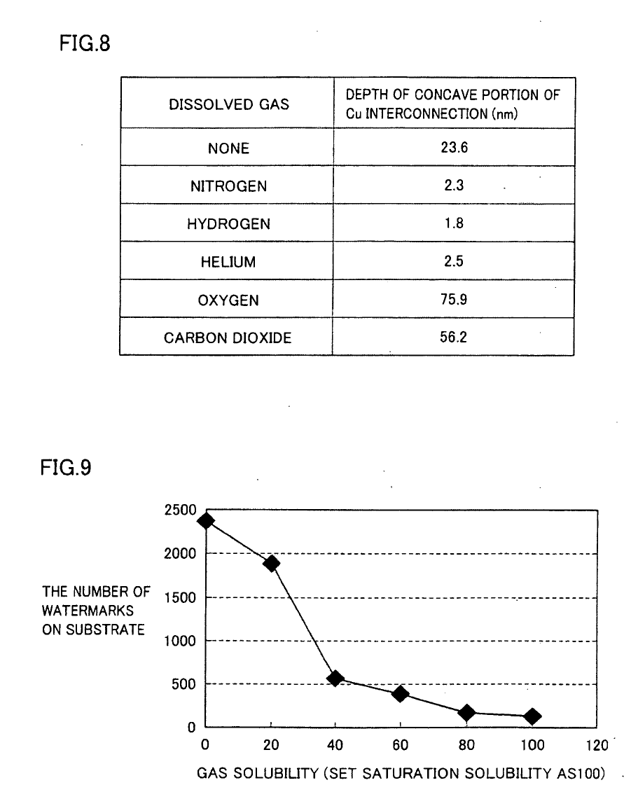

When Cu elutes in Cu interconnection 33, a concave portion is locally formed in Cu interconnection 33 as shown in a dotted circle A in FIG. 7. As for the elution state of Cu interconnection 33, the depth H of the concave portion was obtained at 40 locations of Cu interconnections 33 using the atomic force microscope. The result is shown in FIG. 8. As shown in FIG. 8, when a cleaning liquid with nitrogen gas or helium as inert gas dissolved or a cleaning liquid with hydrogen gas as a reducing gas dissolved is supplied to a semiconductor substrate (case A), the depth of the concave portion of the Cu interconnection is relatively shallow, which shows that the elution of Cu in the Cu interconnection is relatively less. It is confirmed that when a cleaning liquid in which, for example, acetylene, ethylene, carbon monoxide, neon, methane, or the like is dissolved as alternative inert gas or reducing gas is supplied to a semiconductor substrate, the depth of the concave portion of the Cu interconnection is relatively shallow as well.

On the contrary, when a cleaning liquid having no gas dissolved therein (containing no dissolved gas) and a cleaning liquid having oxygen or carbon dioxide dissolved therein as oxidizing gas are respectively supplied to the semiconductor substrate (case B), the depth of the concave portion of the Cu interconnection is deeper by one or more digits as compared with case A. Therefore, it is found that the elution of Cu of the Cu interconnection is significantly increased.

The mechanism of Cu elution can be assumed as follows. First, when the cleaning liquid with oxidizing gas dissolved is supplied to the semiconductor substrate, oxygen dissolves and diffuses in the liquid drop residual on the semiconductor substrate, causing oxygen concentration variations in the drop. When oxygen concentration variations (potential difference) take place, Cu of the Cu interconnection dissolves due to oxygen concentration cell reaction as follows.

2Cu+O₂+2H₂O2Cu(OH)₂

On the other hand, in the case of the cleaning liquid with inert gas dissolved, Cu elution may be prevented since no potential difference or ions exists. Furthermore, in the case of the cleaning liquid with reducing gas dissolved, Cu elution may also be prevented since the oxidizing reaction is prevented.

It is noted that the concave portion of the Cu interconnection formed along with Cu elution clearly differs from the so-called dishing, which occurs across a relatively wide range of a semiconductor substrate by performing CMP process on the semiconductor substrate, and can be observed easily by an atomic force microscope or a scanning electron microscope.

In this way, it is confirmed that the supply of the cleaning liquid with inert gas or reducing gas dissolved to a semiconductor substrate can prevent the formation of watermarks and also prevent Cu elution of the Cu interconnection.

### Fifth Embodiment

The aforementioned evaluations adopted the cleaning liquids having a variety of gases dissolved therein, where each gas was dissolved to a saturation level. Here, the effect of preventing the formation of watermarks will be described where cleaning liquids different in solubility were supplied to a semiconductor substrate. Nitrogen gas was used and the evaluation conditions other than the solubility of nitrogen gas were the same as the conditions described in the first embodiment. The result is shown in FIG. 9.

FIG. 9 is a graph showing the dependence of the number of watermarks on the nitrogen gas solubility, where the horizontal axis shows the solubility with the saturation solubility set at 100 and the vertical axis shows the number of watermarks on the semiconductor substrate. As shown in FIG. 9, as the solubility of nitrogen gas increases, the number of watermarks on the semiconductor substrate tends to decrease accordingly.

It is confirmed that, at 40 of the solubility of nitrogen gas, the number of watermarks significantly reduces to about one-fifth as compared with the case without nitrogen gas dissolved. At 60 of the solubility of nitrogen gas, the number of watermarks even further decreases, and at 80 or more of the solubility of nitrogen gas, watermarks are the fewest in number. It is noted that although the graph shown in FIG. 9 indicates the evaluation result in the case of nitrogen gas, the cleaning liquids in which other inert gas and reducing gas listed in the third embodiment are dissolved respectively in ultrapure water also attain the result similar to that of the cleaning liquid in which nitrogen gas is dissolved in ultrapure water.

In light of the foregoing, the solubility of inert gas or the like in the cleaning liquid is preferably 40% or more of the saturation solubility. More preferably, it is 60% or more, and most preferably, it is 80% or more of the saturation solubility.

### Sixth Embodiment

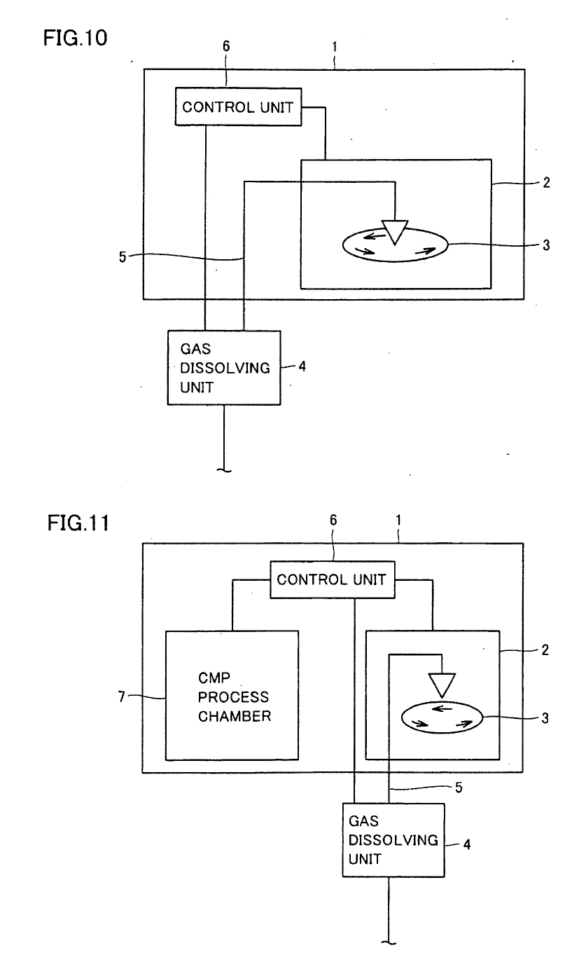

Here, an exemplary semiconductor substrate processing apparatus employed in the method of cleaning a semiconductor substrate as described above will be described. As shown in FIG. 10, a semiconductor processing apparatus 1 is provided with a cleaning process chamber 2 containing a semiconductor substrate 3 for performing a cleaning process on semiconductor substrate 3. Connected to cleaning process chamber 2 is a cleaning liquid feeding pipe 5 for supplying a cleaning liquid to semiconductor substrate 3.

At a midpoint of cleaning liquid feeding pipe 5, provided is a gas dissolving unit 4 for dissolving a prescribed gas in ultrapure water. The gas dissolving unit 4 may be provided with a concentration adjusting function in order to obtain a cleaning liquid with a prescribed gas solubility. A prescribed gas such as inert gas or reducing gas is dissolved in ultrapure water as described above. A control unit 6 is provided having a function of supplying a cleaning liquid in which a prescribed gas is dissolved in ultrapure water to semiconductor substrate 3 that has been subjected to the cleaning process before the drying process.

The operation of semiconductor substrate processing apparatus 1 will now be described. A prescribed cleaning process is performed on semiconductor substrate 3 contained in cleaning process chamber 2. Before a drying process is performed on semiconductor substrate 3 that has been subjected to the cleaning process, a cleaning liquid with inert gas or the like dissolved is supplied (rinsed) to semiconductor substrate 3 through cleaning liquid feeding pipe 5 for a prescribed period of time. A drying process is thereafter performed on semiconductor substrate 3 by rotating semiconductor substrate 3 at a prescribed rotation speed. Semiconductor substrate 3 for which the drying process has been completed is taken out from cleaning process chamber 2, contained in a prescribed carrier, and forwarded to the next step. In this way, a series of processes using semiconductor substrate processing apparatus 1 ends.

In accordance with semiconductor substrate processing apparatus 1 as described above, a cleaning liquid with inert gas or the like dissolved is supplied to semiconductor substrate 3 before the drying process, whereby the diffusion of oxygen into liquid drops left on the surface of semiconductor substrate 3 is prevented and the formation of watermarks on the surface of semiconductor substrate 3 after the drying process can be prevented.

It is noted that although gas dissolving unit 4 is provided outside the processing apparatus body in the semiconductor substrate processing apparatus 1 shown in FIG. 10 by way of example, gas dissolving unit 4 may be provided inside the processing apparatus body. The gas dissolving unit 4 may employ dissolving techniques including a dissolving module such as a hollow fiber film, bubbling using an aeration plate, pipe, or the like, pressurized blowing, negative pressure suction, an ejector, a static mixer, stirring, a contact tower, and the like. It was confirmed that any of those techniques achieved the similar effect.

### Seventh Embodiment

Here, another example of the semiconductor substrate processing apparatus employed in the method of cleaning a semiconductor substrate as described above will be described. As shown in FIG. 11, semiconductor substrate processing apparatus 1 is provided with a CMP process chamber 7 for performing a chemical mechanical polishing process on a semiconductor substrate and cleaning process chamber 2 for cleaning the semiconductor substrate that has been subjected to polishing process in the CMP process chamber 7. This cleaning process chamber 2 has the same function as cleaning process chamber 2 in semiconductor substrate processing apparatus I shown in FIG. 10. Therefore, the same components will be denoted with the same reference characters and the description thereof will not be repeated.

The operation of semiconductor substrate processing apparatus I will now be described. First, a semiconductor substrate (not shown) is contained in CMP process chamber 7 for prescribed polishing process. The semiconductor substrate that has been subjected to the polishing process is taken out from CMP process chamber 7 using a prescribed robot for transfer (not shown) and is then forwarded to cleaning process chamber 2. In cleaning process chamber 2, a large amount of polishing grains and polishing liquid components adhered to the surface of the semiconductor substrate due to the CMP process are cleaned. A cleaning liquid with inert gas or the like dissolved is thereafter supplied to semiconductor substrate 3, and a drying process is performed on semiconductor substrate 3. A series of processes with the semiconductor substrate processing apparatus then ends.

In accordance with the semiconductor substrate processing apparatus I as described above, similarly to the foregoing semiconductor substrate processing apparatus, the diffusion of oxygen into liquid drops left on the surface of semiconductor substrate 3 is prevented by supplying a cleaning liquid with inert gas or the like dissolved before drying, whereby the formation of watermarks on the surface of semiconductor substrate 3 exposed through the CMP process is significantly prevented. In this way, in semiconductor substrate processing apparatus I with CMP process chamber 7, gas dissolving unit 4 is subsidiarily provided to cleaning process chamber 2 for cleaning semiconductor substrate 3 subjected to CMP process, which effectively prevents the formation of watermarks.

It is noted that although here semiconductor substrate processing apparatus 1 is provided with two process chambers, that is, CMP process chamber 7 and cleaning process chamber 2 by way of example, the semiconductor substrate processing apparatus in this manner often employs the CMP process chamber as a main process chamber and the cleaning process chamber as a subsidiary process chamber. In other words, the CMP process chamber is additionally provided with a cleaning function.

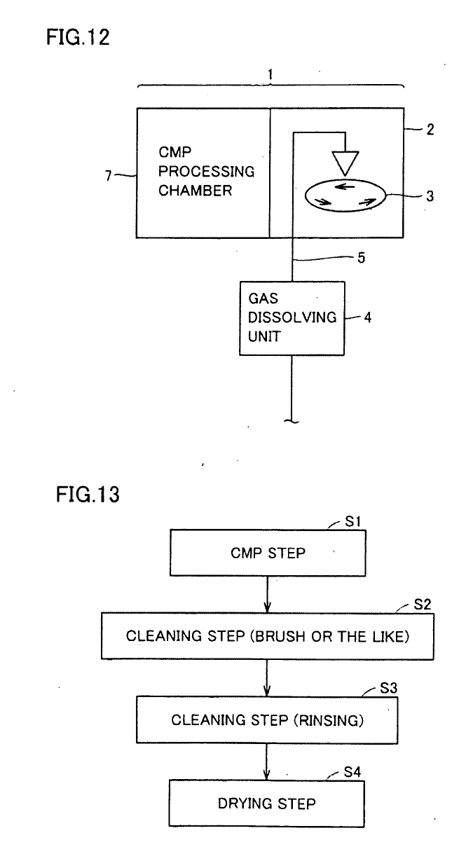

On the other hand, the semiconductor substrate processing apparatus may be a semiconductor substrate processing apparatus 1 in which CMP process chamber 7 and cleaning process chamber 2 are separately provided as shown in FIG. 12. In semiconductor substrate processing apparatus 1 in either case, a cleaning liquid with inert gas or the like dissolved is supplied to semiconductor substrate 3 subjected to CMP process and is then dried, whereby the formation of watermarks on the surface of semiconductor substrate 3 can significantly be prevented.

### Eighth Embodiment

Here, the evaluations performed on product wafers using the above-described semiconductor substrate processing apparatus and the results thereof will be described. The flow is shown in FIG. 13. First, in an CMP process at step S1, Cu interconnections are formed in a semiconductor substrate. Then, in a cleaning process at step S2, a cleaning process is performed on the surface of the semiconductor substrate having Cu interconnections formed therein using a brush and the like. Then, in a cleaning process at step S3, a cleaning liquid with inert gas dissolved is supplied to the semiconductor substrate. Then, in a drying process at step S4, a drying process is performed on the semiconductor substrate.

A series of flows will be described in more detail. First, Low-k film serving as an interlayer insulating film is formed on the surface of the semiconductor substrate. A groove corresponding to an interconnection pattern is formed in the Low-k film. A copper (Cu) film is formed on the Low-k film to fill in the groove. A prescribed CMP process is performed on the semiconductor substrate having the copper film formed thereon, for example, in CMP process chamber 7 shown in FIG. 11, so that Cu interconnection is formed by leaving that portion of the metal film which is located in the groove portion while removing the remaining portion. Here, the Low-k film is exposed together with the Cu interconnection on the surface of the semiconductor substrate.

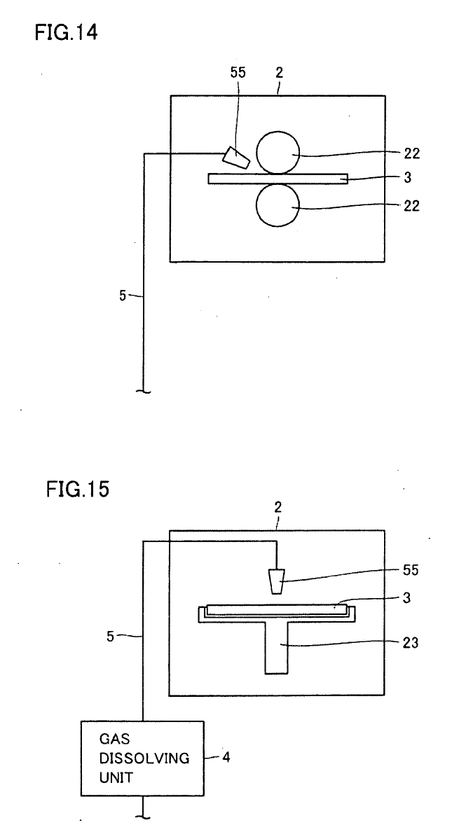

In order to perform a cleaning process on the semiconductor substrate to which a large amount of polishing grains and polishing liquid components adhere due to the CMP process, the semiconductor substrate is taken out from the CMP process chamber and is then transferred to, for example, cleaning process chamber 2 shown in FIG. 14. In cleaning process chamber 2, scrub cleaning is performed on semiconductor substrate 3 using a roll brush 22 of a polymeric material such as polyvinyl alcohol. Here, the scrub cleaning is performed with a cleaning liquid supplied to semiconductor substrate 3 from a nozzle 55 through cleaning liquid feeding pipe 5. It is noted that a prescribed gas is not dissolved in this cleaning liquid.

Before the semiconductor substrate for which scrub cleaning has been completed is dried, as shown in FIG. 15, a cleaning liquid with inert gas or the like dissolved is supplied from nozzle 55 to semiconductor substrate 3 in cleaning process chamber 2. A stage 23 with the semiconductor substrate rested thereon is then rotated at a prescribed rotation speed. The drying process for the semiconductor substrate then ends.

The semiconductor substrate for which a series of processes has been completed as described above was evaluated using a foreign substance inspection apparatus with respect to the formation of watermarks. As a result, it was confirmed that, similarly to the description in the third embodiment, the formation of watermarks was significantly prevented. In addition, the elution of Cu in Cu interconnection was evaluated using an atomic force microscope. As a result, similarly to the description in the fourth embodiment, the concave portion of the Cu interconnection is relatively shallow, which shows that the elution of Cu in Cu interconnection can be prevented.

In accordance with the cleaning method as described above, specifically, the cleaning method is applied to the cleaning process performed on a semiconductor substrate after CMP process in the formation of Cu interconnection, whereby the formation of watermarks can significantly be prevented in the Low-k film exposed on the surface of the semiconductor substrate, and the elution of Cu can significantly be prevented in the Cu interconnection. In addition, specifically, the semiconductor substrate processing apparatus is provided with a cleaning process chamber having a function of dissolving inert gas or the like into ultrapure water, whereby the formation of watermarks is prevented in the semiconductor substrate that has been subjected to the CMP process and the elution of Cu in Cu interconnection is prevented.

It is noted that although, in the evaluations with product wafers in the forgoing description, cleaning process chamber 2 in which a cleaning process using a brush is performed as shown in FIG. 14 and cleaning process chamber 2 to which a cleaning liquid with inert gas or the like dissolved therein is supplied as shown in FIG. 15 are separately provided as cleaning process chambers for a semiconductor substrate after CMP process, the semiconductor substrate processing apparatus may have one cleaning process chamber provided with both a function of cleaning using a brush and a function of supplying a cleaning liquid with inert gas or the like dissolved therein.

Furthermore, although an SiOC film has been described as Low-k film by way of example, the present invention is not limited to the SiOC film and may include any film having a structure in which carbon and hydrogen are incorporated. For example, CDO (Carbon Doped Oxide) film, MSQ (Methyl Silsequioxane) film, HSQ (Hydrogen Silsequioxane) film, FSQ (Fluoride Silsequioxane) film, DLC (Diamond Like Carbon) film, an organic polymer film such as polyarylen or parylene may be employed. Alternatively, porous Low-k film may be employed.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A method of manufacturing a semiconductor device comprising:
a step of forming a porous Low-k film exhibiting hydrophobicity at a main surface of a semiconductor substrate;
a step of forming a prescribed groove corresponding to an interconnection pattern in said porous Low-k film exhibiting hydrophobicity;
a step of forming a metal film on said porous Low-k film exhibiting hydrophobicity to fill in said groove;
a step of forming an interconnection in said groove by performing a chemical mechanical polishing process on said metal film for selectively leaving said metal film in said groove;
a first cleaning step of cleaning the surface of said semiconductor substrate after said chemical mechanical polishing process;
a second cleaning step of cleaning the surface of said semiconductor substrate after said first cleaning step; and
a step of drying the surface of said semiconductor substrate after said second cleaning step, wherein
a cleaning liquid in which a reducing gas or an inert gas is dissolved is used in said second cleaning step.

2. The method of manufacturing a semiconductor device according to claim 1, wherein
said first cleaning step includes a scrub cleaning process of cleaning a surface of said semiconductor substrate using a brush, and
said second cleaning step includes a spin cleaning process of rotating said semiconductor substrate during cleaning.

3. The method of manufacturing a semiconductor device according to claim 1, wherein said second cleaning step includes cleaning using as said cleaning liquid a cleaning liquid in which at least one of a reducing gas and an inert gas is dissolved.

4. The method of manufacturing a semiconductor device according to claim 1, wherein said interlayer insulating film includes a Low-k film having a dielectric constant of 2.0 to 3.7.

5. The method of manufacturing a semiconductor device according to claim 1, wherein said metal film includes at least copper (Cu).

6. The method of manufacturing a semiconductor device according to claim 1, wherein a solubility of said gas to be dissolved in said cleaning liquid is at least 40% of a saturation solubility of said gas to be dissolved with respect to said cleaning liquid.

7. The method of manufacturing a semiconductor device according to claim 1, wherein a solubility of said gas to be dissolved in said cleaning liquid is at least 60% of a saturation solubility of said gas to be dissolved with respect to said cleaning liquid.

8. The method of manufacturing a semiconductor device according to claim 1, wherein a solubility of said gas to be dissolved in said cleaning liquid is at least 80% of a saturation solubility of said gas to be dissolved with respect to said cleaning liquid.
